(19) United States
(12) Patent Application Publication
(10) Pub. No.: US 2026/0040849 A1
(43) Pub. Date: Feb. 5, 2026

(54) SEMICONDUCTOR DEVICE MANUFACTURING METHOD AND SEMICONDUCTOR DEVICE

(71) Applicants: Gigaphoton Inc., Tochigi (JP); KYUSHU UNIVERSITY, NATIONAL UNIVERSITY CORPORATION, Fukuoka (JP)

(72) Inventors: Yohei TANAKA, Oyama-shi (JP); Hisato YABUTA, Fukuoka-Shi (JP); Misa BEPPU, Fukuoka-shi (JP); Keita KATAYAMA, Fukuoka-shi (JP)

(73) Assignees: Gigaphoton Inc., Tochigi (JP); KYUSHU UNIVERSITY, NATIONAL UNIVERSITY CORPORATION, Fukuoka (JP)

(21) Appl. No.: 19/262,756

(22) Filed: Jul. 8, 2025

(30) Foreign Application Priority Data
Aug. 5, 2024 (JP) 2024-129183

(51) Int. Cl. H01L 21/385; H01L 21/02; H10D 62/80

(52) U.S. Cl. CPC H01L 21/385; H01L 21/02565; H10D 62/875

(57) ABSTRACT

A semiconductor device manufacturing method includes forming a tin-containing oxide film on a gallium-oxide-based compound; irradiating the tin-containing oxide film with ultraviolet laser light to dope the gallium-oxide-based compound with tin; and forming a metal electrode on the tin-containing oxide film irradiated with the ultraviolet laser light.

### CROSS-REFERENCE TO RELATED APPLICATIONS

The present application claims the benefit of Japanese Patent Application No. 2024-129183, filed on Aug. 5, 2024, the entire contents of which are hereby incorporated by reference.

### BACKGROUND

### 1. Technical Field

The present disclosure relates to a semiconductor device manufacturing method, and a semiconductor device.

### 2. Related Art

At present, energy consumption continues to increase along with economic growth, while reduction in greenhouse gas emissions is required due to the climate change. There is therefore a demand for development of power electronics technologies for realizing efficient energy supply. Power electronics is a technology for converting and controlling electric energy, and the semiconductors used in power electronics circuits are called power devices (power semiconductors). Silicon (Si) has been used as a material for the power devices, but Si is reaching its limit in terms of performance improvement. As alternative materials, research and development of silicon carbide (SiC) and gallium nitride (GaN), which have a band gap wider than that of Si, has been underway. These materials can realize higher-voltage-resistant, low-loss devices as compared with Si-based devices, but have problems of requiring an expensive substrate and having difficulty in mass production.

To address the problems described above, β-gallium oxide (β-Ga₂O₃), which has a band gap wider than those of 4H—SiC and GaN, attracts attention as a next-generation power device material. β-Ga₂O₃ has a very wide band gap and therefore has material properties superior to those of SiC and GaN. In addition, since the melt growth method can be used to grow a bulk of single crystal, it is expected that Ga₂O₃ power devices can be produced at low cost in large quantity. However, research and development of Ga₂O₃ devices has been delayed because the excellent properties of the material have not been fully utilized.

### CITATION LIST

### Patent Literature

[PTL 1] U.S. Pat. No. 8,207,003
[PTL 2] JP-A-2020-076153
[PTL 3] U.S. Pat. No. 5,413,959
[PTL 4] JP-A-8-264468
[PTL 5] JP-A-4-250617

### SUMMARY

A semiconductor device manufacturing method according to an aspect of the present disclosure includes forming a tin-containing oxide film on a gallium-oxide-based compound; irradiating the tin-containing oxide film with ultraviolet laser light to dope the gallium-oxide-based compound with tin; and forming a metal electrode on the tin-containing oxide film irradiated with the ultraviolet laser light.

A semiconductor device according to another aspect of the present disclosure includes a gallium-oxide-based compound, and a tin-containing oxide film formed on the gallium-oxide-based compound. An Sn concentration in the tin-containing oxide film is higher than or equal to 10²¹ atoms/cm³ when the tin-containing oxide film is irradiated with ultraviolet laser light to dope the gallium-oxide-based compound with tin. An Sn concentration in the tin-doped gallium-oxide-based compound is lower than 10²¹ atoms/cm³. An Sn concentration in a portion from an interface between the tin-containing oxide film and the gallium-oxide-based compound to a depth of 10 nm is higher than or equal to 10¹⁸ atoms/cm³.

### BRIEF DESCRIPTION OF DRAWINGS

Some embodiments of the present disclosure will be described below only by way of example with reference to the accompanying drawings.

FIG. 1 schematically shows an example of the configuration of a laser doping system.

FIG. 2 shows a comparison between the physical properties of β-Ga₂O₃ and those of major semiconductor materials.

FIG. 3 is a descriptive diagram showing an overview of a semiconductor device manufacturing method according to Comparative Example.

FIG. 4 is a flowchart of a semiconductor device manufacturing method according to an embodiment.

FIG. 5 is a descriptive diagram showing an overview of the semiconductor device manufacturing method according to the embodiment.

FIG. 6 is a diagrammatic cross-sectional view showing an example of the structure of a semiconductor device produced by using the semiconductor device manufacturing method according to the embodiment.

FIG. 7 is a diagrammatic cross-sectional view showing an example of the structure of a currently proposed power device.

FIG. 8 is a graph showing an example of the distribution of the Sn concentration in Ga₂O₃ doped with tin (Sn) by using processes described in the embodiment.

### DETAILED DESCRIPTION

Contents
1. Example of laser doping system
1.1 Configuration
1.2 Operation
2. Specific examples of semiconductor material
2.1 Physical properties and crystal phases of Ga₂O₃
2.2 Physical properties of β-Ga₂O₃
2.3 Process of implanting dopant into β-Ga₂O₃
2.3.1 Dopants for β-Ga₂O₃
2.3.2 Ion implantation method
2.3.3 Laser doping method
3. Semiconductor device manufacturing method according to Comparative Example
4. Problems
5. Embodiment
5.1 Configuration
5.2 Operation
5.3 Effects and advantages
6. Application examples of device production
6.1 Application example 1
6.2 Application example 2
7. Example of Sn concentration distribution
8. Processor
9. Others

An embodiment of the present disclosure will be described below in detail with reference to the drawings. The embodiment described below shows some examples of the present disclosure and is not intended to limit the contents of the present disclosure. Furthermore, all configurations and operations described in the embodiment are not necessarily essential as configurations and operations in the present disclosure. The same element has the same reference character, and no redundant description of the same element will be made.

### 1. EXAMPLE OF LASER DOPING SYSTEM

### 1.1 Configuration

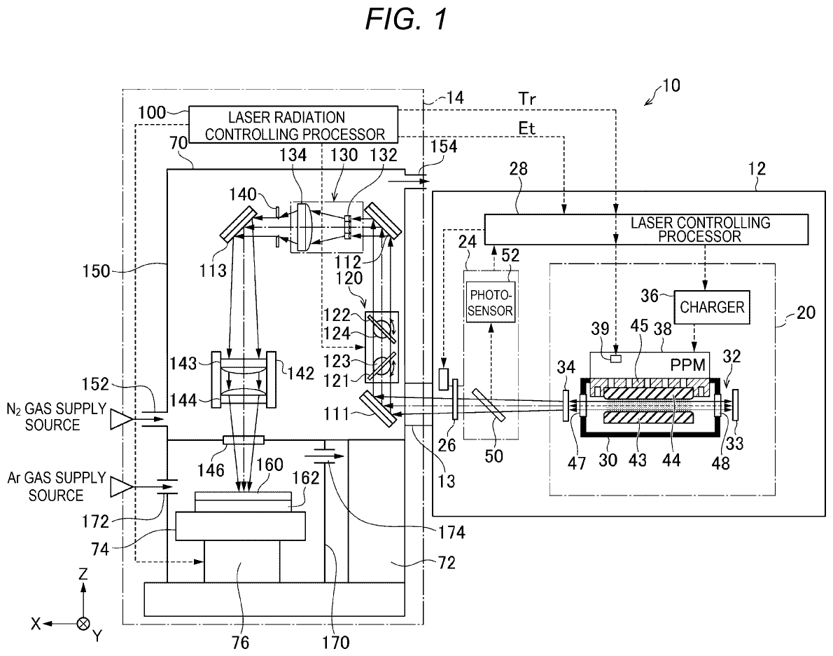

FIG. 1 schematically shows an example of the configuration of a laser doping system 10. The laser doping system 10 includes a laser apparatus 12, an optical path tube 13, and a laser radiating apparatus 14. The laser apparatus 12 is a laser apparatus that outputs pulse laser light having photon energy higher than the band gap of a semiconductor material. For example, the laser apparatus 12 may be a discharge-excitation-type ultraviolet laser apparatus using a laser medium made of F₂, ArF, or KrF. The laser apparatus 12 may instead be a solid-state laser apparatus that outputs light having an ultraviolet wavelength.

The laser apparatus 12 includes an oscillator 20, a monitor module 24, a shutter 26, and a laser controlling processor 28.

The oscillator 20 includes a chamber 30, an optical resonator 32, a charger 36, and a pulse power module (PPM) 38.

The chamber 30 encapsulates an excimer laser gas. The chamber 30 includes a pair of electrodes 43 and 44, an insulating member 45, and windows 47 and 48.

The optical resonator 32 is configured with a rear mirror 33 and an output coupler (OC) 34. The rear mirror 33 and the OC 34 are each configured with a planar substrate coated with a highly reflective film and a partially reflective film. The chamber 30 is disposed in the optical path of the optical resonator 32.

The PPM 38 includes a switch 39 and a charging capacitor that is not shown. The switch 39 is connected to a signal line along which a control signal from the laser controlling processor 28 is transmitted.

The charger 36 is connected to the charging capacitor of the PPM 38. The charger 36 receives charging voltage data from the laser controlling processor 28 and charges the charging capacitor of the PPM 38.

The monitor module 24 includes a beam splitter 50 and a photosensor 52.

The shutter 26 is disposed in the optical path of the pulse laser light output from the monitor module 24. The optical path of the pulse laser light may be encapsulated by an enclosure that is not shown and the optical path tube 13 and purged, for example, with an inert gas such as an N₂ gas.

The laser radiating apparatus 14 includes a radiation optical system 70, a frame 72, an XYZ stage 76, a table 74, and a laser radiation controlling processor 100.

The radiation optical system 70 includes highly reflective mirrors 111, 112, and 113, an attenuator 120, a beam homogenizer 130, a mask 140, a transfer optical system 142, a window 146, and an enclosure 150.

The highly reflective mirror 111 is so disposed that the pulse laser light output by the laser apparatus 12 passes through the attenuator 120 and is incident on the highly reflective mirror 112.

The attenuator 120 is disposed in the optical path between the highly reflective mirror 111 and the highly reflective mirror 112. The attenuator 120 includes two partially reflective mirrors 121 and 122 and rotary stages 123 and 124, which can change the angles of incidence of the pulse laser light incident on the partially reflective mirrors 121 and 122.

The highly reflective mirror 112 is so disposed that the pulse laser light having passed through the attenuator 120 passes through the beam homogenizer 130 and the mask 140 and is incident on the highly reflective mirror 113. The beam homogenizer 130 and the mask 140 are disposed in the optical path between the highly reflective mirror 112 and the highly reflective mirror 113.

The beam homogenizer 130 includes a fly eye lens 132 and a condenser lens 134 and is so disposed that the mask 140 is illuminated in Koehler illumination.

The highly reflective mirror 113 is so disposed that the pulse laser light incident via the beam homogenizer 130 passes through the transfer optical system 142 and the window 146 and is radiated onto a dopant thin film 160 containing a dopant. The dopant is an element with which a semiconductor material 162 is doped through laser doping.

The transfer optical system 142 is so located that an image of the mask 140 is formed through the window 146 at the surface of the dopant thin film 160 formed on the semiconductor material 162.

The transfer optical system 142 may be a combination lens configured with multiple lenses 143 and 144 and may be a reduction projection optical system.

The window 146 is located in the optical path between the transfer optical system 142 and a radiation receiving object, and disposed in a hole of the enclosure 150, for example, via an O-ring that is not shown.

The enclosure 150 may be provided with an inlet 152 and an outlet 154, via which an N₂ gas is introduced and discharged, and may be sealed, for example, with an O-ring that is not shown to prevent outside air from entering the enclosure 150.

The radiation optical system 70 and the XYZ stage 76 are fixed to the frame 72. The table 74 is disposed on the XYZ stage 76, and an irradiation target is placed on the table 74.

The semiconductor material 162 may, for example, be Ga₂O₃. The semiconductor material 162 is held by the XYZ stage 76 via the table 74.

The dopant thin film 160 containing a dopant is formed at the surface of the semiconductor material 162. The dopant thin film 160 may, for example, be an SnO₂ film or an ITO film.

A radiation shield 170, which covers the surroundings around the table 74 including the space between the window 146 and the irradiation receiving object, is sealed, for example, with an O-ring that is not shown, and has a configuration in which out of the space between the window 146 and the irradiation receiving object, at least a space above the surface of the irradiation receiving object can be filled with a purge gas. The radiation shield 170 is provided with an inlet 172 and an outlet 174, via which the purge gas is introduced and discharged. Instead of using a purge gas, the outlet 174 may be connected to a vacuum pump that is not shown with the inlet 172 closed, and the semiconductor material 162, of which the irradiation receiving object is made, may be placed in a vacuum environment.

The purge gas may, for example, be dry air, oxygen, nitrogen gas, argon gas, or helium gas. The laser light radiation may be performed in the vacuum or atmospheric environment without use of a purge gas.

The window 146 may be a substrate made of CaF₂ crystal or synthetic quartz, which transmits excimer laser light, and may be coated with reflection suppression films on opposite sides.

### 1.2 Operation

The operation of the laser doping system 10 will be described. The laser radiation controlling processor 100 reads radiation condition parameters used when the laser doping is performed. Specifically, the laser radiation controlling processor 100 reads fluence Fd used when the laser doping is performed. The fluence Fd varies in accordance with the material and film thickness of the irradiation receiving object, and should therefore be identified in advance, for example, through experiments.

The laser radiation controlling processor 100 sets target pulse energy Et and transmittance Td of the attenuator 120 based on the fluence Fd at the surface of the irradiation receiving object, and causes the rotary stages 123 and 124 to control the angles of incidence of pulse laser light incident on the two partially reflective mirrors 121 and 122 in such a way that the attenuator 120 has the transmittance Td.

The laser radiation controlling processor 100 first controls the movement of the XYZ stage 76 along the X-axis and the Y-axis in such a way that the image of the mask 140 is formed at the irradiated region of the semiconductor material 162. The laser radiation controlling processor 100 then controls the movement of the XYZ stage 76 along the Z-axis in such a way that the image of the mask 140 is formed at the position of the surface of the dopant thin film 160 formed on the semiconductor material 162.

The laser radiation controlling processor 100 causes the laser apparatus 12 to output the pulse laser light. The laser radiation controlling processor 100 transmits the target pulse energy Et and a light emission trigger Tr to the laser controlling processor 28.

The pulse laser light output from the oscillator 20 is sampled by the beam splitter 50 of the monitor module 24, and pulse energy E is measured with the photosensor 52. The laser controlling processor 28 controls the charging voltage from the charger 36 in such a way that a difference ΔE between the pulse energy E and the target pulse energy Et approaches zero.

The pulse laser light having passed through the beam splitter 50 of the monitor module 24 enters the laser radiating apparatus 14 via the optical path tube 13. The pulse laser light having entered the laser radiating apparatus 14 is reflected off the highly reflective mirror 111, attenuated by the attenuator 120, and reflected off the highly reflective mirror 112.

The pulse laser light reflected off the highly reflective mirror 112 is spatially homogenized in terms of optical intensity by the beam homogenizer 130 and is incident on the mask 140. It is preferable that the beam shape of the pulse laser light with which the mask 140 is uniformly illuminated is larger than holes in the mask 140 and substantially coincides with the shape of the mask.

The pulse laser light having passed through the mask 140 is reflected off the highly reflective mirror 113, transferred by the transfer optical system 142, and brought into focus at the surface of the dopant thin film 160, which is thus irradiated with the pulse laser light. As a result, the dopant thin film 160 and the semiconductor material 162 are heated, so that the dopant is diffused into the semiconductor material 162 with the aid of thermal diffusion and thermal shock waves.

The laser radiation controlling processor 100 controls the movement of the XYZ stage 76 along the X-axis and the Y-axis in such a way that the following irradiated region of the semiconductor material 162 is irradiated with the pulse laser light.

The operation described above is performed on the regions of the semiconductor material 162 that are to be irradiated. The irradiated regions are each irradiated with the pulse laser light at a rate ranging from 1 to 100,000 pulses. The laser doping system 10 may thus expose the semiconductor material 162 to the pulse laser light in a step-and-repeat manner.

### 2. SPECIFIC EXAMPLES OF SEMICONDUCTOR MATERIAL

### 2.1 Physical Properties and Crystal Phases of Ga₂O₃

Ga₂O₃ exhibits crystal polymorphism and has five crystal phases, α, β, γ, δ, and ε(κ). Out of the five crystal phases, the β phase has the most thermodynamically stable phase, and the other phases have metastable phases. Research and development of Ga₂O₃ devices is therefore underway primarily on β-Ga₂O₃. The β-phase crystal structure is a monoclinic β-gallia structure, and out of the five phases, only the β phase can be grown into a bulk of single crystal by the melt growth method. The phases other than the β phase have been attracting attention in recent years because they have unique properties not seen in the β phase. The α phase, which has a corundum structure, can be easily formed into a thin film through hetero-epitaxial growth on a sapphire substrate, which also has a corundum structure. The α phase is therefore the second most researched, following the β phase. The γ phase has a defect spinel structure, and the δ phase has a cubic bixbyite structure. Since the ε(κ) phase has spontaneous polarization, it is expected that a high-concentration two-dimensional electron gas (2DEG) is formed at the (AlGa)₂O₃/Ga₂O₃ interface, as in the case of an AlGaN/GaN heterojunction. The metastable-phase thin films described above, when treated at high temperatures, undergo transformation to the β phase, which is the most stable phase, and therefore have a problem being treated only at low temperatures.

### 2.2 Physical Properties of β-Ga₂O₃

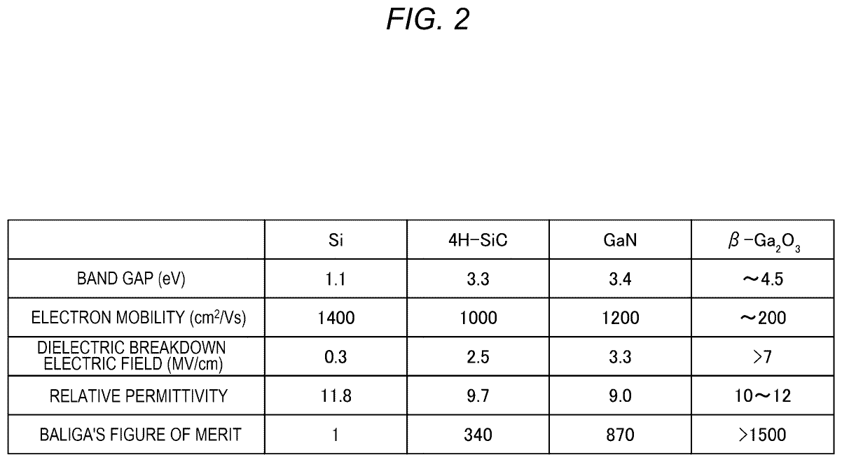

FIG. 2 shows a comparison between the physical properties of β-Ga₂O₃ and those of major semiconductor materials. The most outstanding feature of β-Ga₂O₃ is a very wide band gap of about 4.5 eV. β-Ga₂O₃ has a band gap wider than those of wide-band-gap energy semiconductors such as 4H—SiC and GaN, and is called an ultra-wide-band-gap energy semiconductor. The large band gap predicts that the dielectric breakdown electric field is greater than or equal to 7 MV/cm, which is twice greater than or equal to those of 4H—SiC and GaN. A large dielectric breakdown electric field allows reduction in the thickness of a drift layer or an increase in impurity concentration, so that the on-resistance can be reduced.

The Baliga's figure of merit is an index of the performance of a power device on the assumption that the Baliga's figure of merit of Si is one, and is a value determined by the permittivity, electron mobility, and dielectric breakdown electric field. Since the Baliga's figure of merit is proportional to the cube of the dielectric breakdown electric field, the Baliga's figure of merit of β-Ga₂O₃ is greater than those of other materials. The greater the Baliga's figure of merit, the smaller the on-resistance, so that it is expected that a small amount of loss can be achieved.

### 2.3 Process of Implanting Dopant into β-Ga₂O₃

This section describes dopants to be implanted into β-Ga₂O₃ and provides an overview of an ion implantation method and a laser doping method that are the most commonly used methods for implanting dopants into β-Ga₂O₃.

2.3.1 Dopants for β-Ga₂O₃

The electrical conductivity of a semiconductor can be changed by implanting impurities called dopants into the semiconductor. Dopants include donors and acceptors. When a donor is implanted into a semiconductor, free electrons are supplied to the semiconductor, which becomes an n-type semiconductor, while when an acceptor is implanted into a semiconductor, holes are supplied to the semiconductor, which becomes a p-type semiconductor. The free electrons and holes are called carriers and play a role in transporting electric charges. Regarding β-Ga₂O₃, research and development of n-type semiconductors is underway, but no results have been reported on p-type semiconductors.

The β-Ga₂O₃ structure is a monoclinic β-gallia structure as described above, and there are two types of Ga sites: Ga(1) with a coordination number of 4; and Ga(2) with a coordination number of 6. It is expected that carriers are generated by implanting a dopant into β-Ga₂O₃ to substitute the Ga sites with the dopant.

Examples of n-type dopants for β-Ga₂O₃ include Si, Sn, and Ge. Si and Ge tend to substitute for Ga(1), and Sn tends to substitute for Ga(2). In either case, a shallow donor level is formed.

### 2.3.2 Ion Implantation Method

The ion implantation method is a technology widely used to implant a dopant into a semiconductor. The properties of a substrate can be changed by ionizing the atoms or molecules of a dopant, accelerating the ionized atoms or molecules to cause them to have energy from a few keV to a few MeV, and implanting them into the substrate. The procedure of doping into β-Ga₂O₃ by the ion implantation method is as follows: first, the ions are implanted into β-Ga₂O₃ at room temperature, and then the resultant β-Ga₂O₃ is annealed at a temperature from 900 to 1000° C. to activate the implanted dopant. The contact specific resistance of a device produced by using the ion implantation method provided a favorable value of 4.6×10⁻⁶ Ωcm², so that ohmic contact was formed. The ion implantation method has thus provided results sufficiently practical in the β-Ga₂O₃ device production. The ion implantation method, however, requires high-temperature annealing after the ion implantation to activate the implanted dopant, which makes the process complicated.

### 2.3.3 Laser Doping Method

The laser doping method is a technology for implanting a dopant into a semiconductor through laser radiation. Laser doping is performed by irradiating a substrate with laser light in a gas atmosphere or a solution containing dopant atoms, or by depositing a dopant thin film on a substrate and irradiating the dopant thin film with laser light, and the latter method is employed in the embodiment of the present disclosure. When a dopant thin film is deposited on a semiconductor substrate and irradiated with laser light, the dopant is diffused into the semiconductor substrate by the heat generated by the laser light. In this process, the substrate does not melt, and the dopant is implanted through solid-phase diffusion. The advantage of the laser doping is a simplified process that does not require high-temperature annealing to activate the dopant. Another advantage of the laser doping is formation of a heavily doped layer in a shallow region at a depth of several tens of nanometers to hundred nanometers.

### 3. SEMICONDUCTOR DEVICE MANUFACTURING METHOD ACCORDING TO COMPARATIVE EXAMPLE

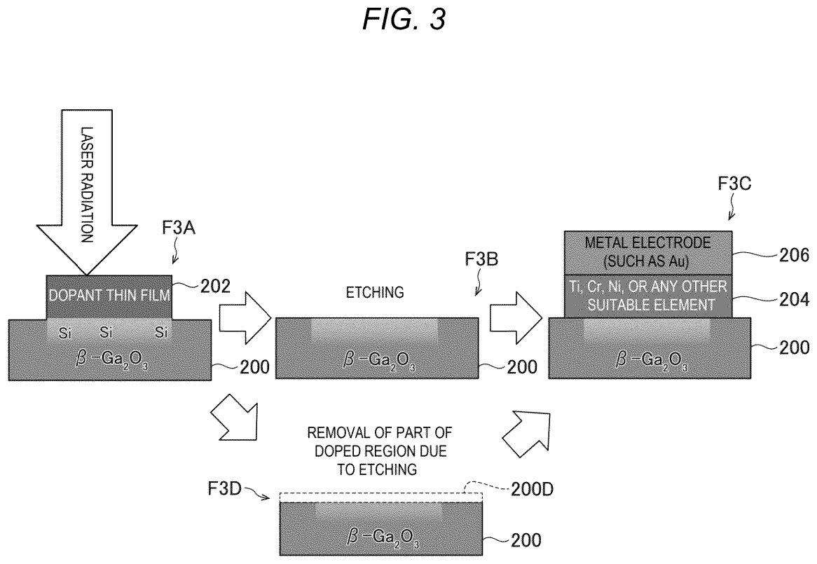

FIG. 3 is a descriptive diagram showing an overview of a semiconductor device manufacturing method according to Comparative Example. Comparative Example of the present disclosure is an aspect that the applicant is aware of as known only by the applicant, and is not a publicly known example that the applicant is self-aware of. For example, the step of performing laser doping on a β-Ga₂O₃ semiconductor and then forming an electrode is shown below.
[Step 1] A dopant thin film 202 is formed on a β-Ga₂O₃ semiconductor 200 as a dopant supply source. The dopant thin film 202 is, for example, an a-Si (amorphous silicon) film.
[Step 2] The dopant thin film 202 is irradiated with pulse laser light from above, so that the interior of the semiconductor material is doped with the dopant in the dopant thin film 202 (see F3A in left portion of FIG. 3).
[Step 3] The dopant thin film 202 is removed by etching (see F3B in upper center portion of FIG. 3).
[Step 4] Thereafter, a metal film 204 made of titanium (Ti), chromium (Cr), nickel (Ni), or any other metal material that is unlikely to be oxidized is formed, and then a gold (Au) film is formed as an electrode 206 (see F3C in right portion of FIG. 3).

### 4. PROBLEMS

In the semiconductor device manufacturing method according to Comparative Example, formation of an electrode on the β-Ga₂O₃ semiconductor 200 after the doping requires removal of the dopant thin film 202 formed on the β-Ga₂O₃ semiconductor 200 through etching or any other technique, which makes the manufacturing steps complicated.

Furthermore, when the dopant thin film 202 is not made of a selectively removable material, the removal of the dopant thin film 202 has a risk of removing a portion 200D of the surface of the doped β-Ga₂O₃ layer (see F3D in lower portion of FIG. 3). This leads to limited selection of the doping range and etching method.

### 5. EMBODIMENT

### 5.1 Configuration

The configuration of a laser doping system used in a semiconductor device manufacturing method according to an embodiment may be the same as that of the laser doping system 10 shown in FIG. 1. The pulse laser light output from the laser apparatus 12 is an example of the “ultraviolet laser light” in the present disclosure.

### 5.2 Operation

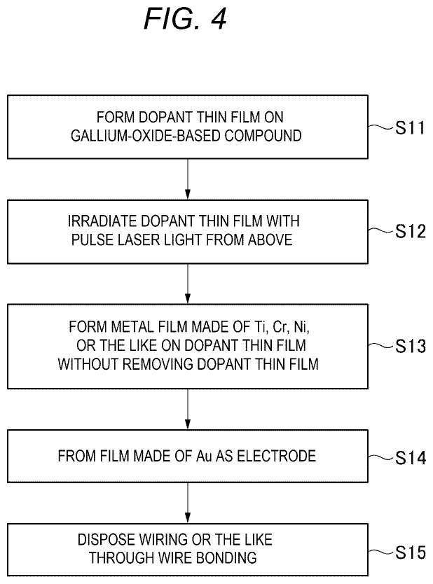

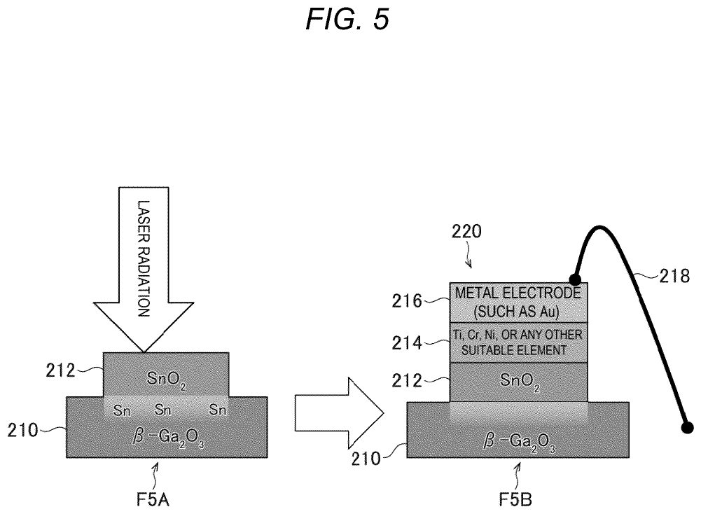

FIG. 4 is a flowchart of the semiconductor device manufacturing method according to the embodiment, and FIG. 5 shows an overview of processes of the method.

In step S11, a dopant thin film 212 is formed on a gallium-oxide-based compound 210, which is a semiconductor material. The dopant thin film 212 is, for example, a tin dioxide (SnO₂) film having a film thickness greater than or equal to 1 nm but smaller than or equal to 300 nm formed by sputtering, pulsed laser deposition (PLD), or any other method. The gallium-oxide-based compound 210 may, for example, be β-Ga₂O₃, or another phase of Ga₂O₃ (a-Ga₂O₃, for example), or may be (In, Ga) 203 or In—Ga—Zn—O. SnO₂ may be replaced with tin monoxide (SnO) or SnOx, x being a non-integer. SnO₂ may instead be replaced with any other oxide containing Sn, for example, In₂O₃:Sn (ITO: indium tin oxide or tin-doped indium oxide) or In—Ga—Sn—O. The oxides described above may each have a single crystal state, or a polycrystalline or amorphous state.

In step S12, the dopant thin film 212 is irradiated with pulse laser light from above, so that the interior of the semiconductor material is doped with tin (Sn) in the SnO₂ film as the dopant (see F5A in left portion of FIG. 5). The conditions under which the pulse laser light is radiated need to be so set that the intensity of the pulse laser light is lower than or equal to a threshold at which Ga₂O₃, which is the lower layer, is damaged, and that the flatness of the SnO₂ surface does not impede the formation of a metal electrode that is the upper layer. For example, when KrF excimer laser light (having wavelength of 248 nm) is used, the laser fluence at the SnO₂ film may be smaller than or equal to 400 mJ/cm², preferably, greater than or equal to 100 mJ/cm² but smaller than or equal to 400 mJ/cm².

In step S13, the SnO₂ film, which is the dopant thin film 212, is not removed, but a metal film 214 made of Ti, Cr, Ni, or the like is formed on the SnO₂ film. The dopant thin film 212 is a thin film having electrical conductivity and can therefore be used as a portion of the electrode.

After step S13, a film made of Au or the like is formed as an electrode 216 on the metal film 214 in step S14. The electrode 216 is an example of the “metal electrode” in the present disclosure. Note that the metal film 214 and the electrode 216 may constitute the metal electrode.

After step S14, wiring 218 and the like may be disposed by wire bonding or the like in step S15 (see F5B in right portion of FIG. 5).

In a thus produced semiconductor device 220, the dopant thin film 212 used as the dopant supply source functions as a contact electrode. The contact electrode refers to an electrode material used as a combination of different materials that provide low electrical resistance (contact resistance) at the interface (contact surface) between the materials.

### 5.3 Effects and Advantages

The semiconductor device manufacturing method according to the embodiment provides the advantages below.
[1] There is no need to provide the step of removing the dopant thin film 212 through etching or the like after the laser doping step (step S12). The manufacturing steps are therefore simplified, and the etching does not erode the surface of the β-Ga₂O₃ layer.
[2] The SnO₂ film itself, which serves as the dopant supply source, serves as an ohmic electrode with respect to Ga₂O₃, so that the electrical resistance between the electrode 216 and the Ga₂O₃ semiconductor decreases, and electrical loss and heat generation can be reduced accordingly.
[3] A heavily doped layer is left at the outermost β-Ga₂O₃ surface, so that the contact resistance decreases, and power loss in the device is suppressed.

### 6. APPLICATION EXAMPLES OF DEVICE PRODUCTION

### 6.1 Application Example 1

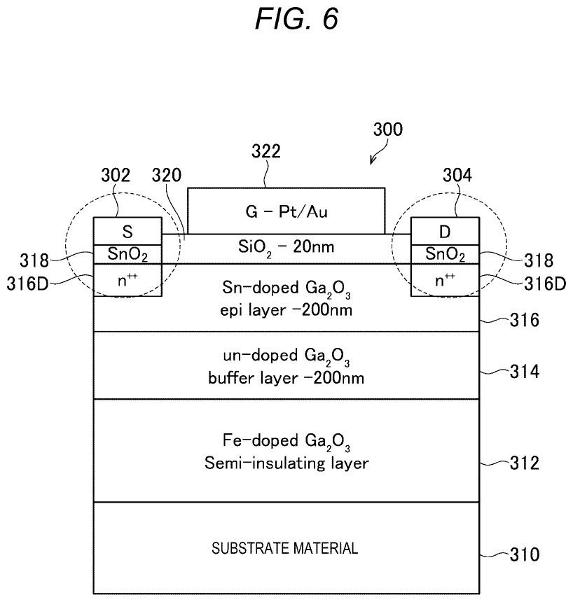

FIG. 6 shows an example of the structure of a semiconductor device 300 produced by using the semiconductor device manufacturing method according to the embodiment. Elements made of Ga₂O₃, which has a difficulty in producing p-type elements, are limited to only n-type devices. For example, in a device structure shown in FIG. 6, it is necessary to form a high-concentration n⁺⁺ layer near the interface at each of a source(S) electrode 302 and a drain (D) electrode 304, as shown in the portions surrounded by the broken-line circles in FIG. 6.

The steps of manufacturing the semiconductor device 300 shown in FIG. 6 are shown below.
[Step 21] An Fe-doped Ga₂O₃ layer 312, which is an insulating layer, is layered on a substrate material 310. The substrate material 310 may be sapphire or the like in place of Ga₂O₃.
[Step 22] A un-doped Ga₂O₃ layer 314 is layered as a buffer layer on the Fe-doped Ga₂O₃ layer 312.
[Step 23] A Ga₂O₃ layer 316 lightly doped with Sn is layered on the un-doped Ga₂O₃ layer 314. The Sn concentration in the Sn-doped Ga₂O₃ layer 316 may, for example, be approximately lower than 3×10¹⁶ atoms/cm³.
[Step 24] SnO₂ layers 318 are layered on the Sn-doped Ga₂O₃ layer 316 at the positions where the source(S) electrode 302 and the drain (D) electrode 304 are formed. The SnO₂ layers 318 are an example of the “tin-containing oxide film” in the present disclosure.
[Step 25] The SnO₂ layers 318 are irradiated with laser light to form n⁺⁺ layers 316D heavily doped with Sn near the outermost surface of the Ga₂O₃ layer 316. The Sn concentration in the n⁺⁺ layers 316D may, for example, be higher than or equal to approximately 1×10¹⁸ atoms/cm³.
[Step 26] An SiO₂ layer 320 is then layered as a gate insulating film on the Ga₂O₃ layer 316.
[Step 27] The electrodes 302 and 304 are then formed with the SnO₂ layers 318 not removed, and an electrode 322 is formed on the SiO₂ layer 320.

### 6.2 Application Example 2

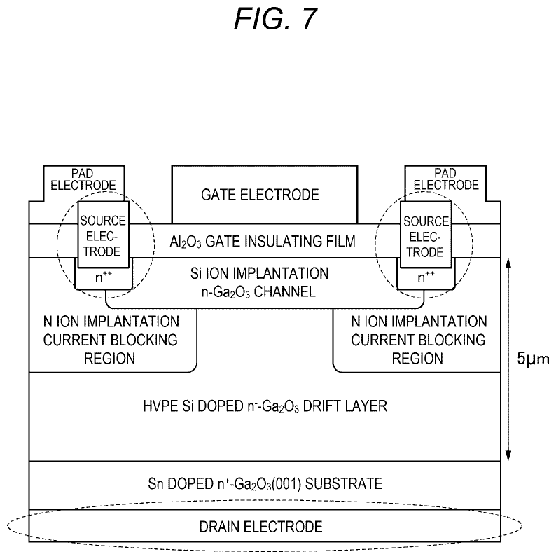

FIG. 7 is a diagrammatic cross-sectional view showing an example of the structure of a currently proposed Ga₂O₃ power device. The structure of the vertical depletion mode Ga₂O₃ transistor shown in FIG. 7 is described, for example, in M. H. Wong, K. Goto, H. Murakami, Y. Kumagai, and M. Higashiwaki, “Current aperture vertical β-Ga₂O₃ MOSFETs fabricated by N- and Si-ion implantation doping,” IEEE Electron Device Lett., vol. 40, no. 3, pp. 431-434, March 2019, and Masataka Higashiwaki and Takafumi Kamimura, “Environment Control ICT Basic Research—from Researches to Applications—Research and Development on Gallium Oxide Electronic Devices,” National Institute of Information and Communications Technology Report vol. 66 No. 2 (2020) (https://www.nict.go.jp/publication/shuppan/kihou-journal/houkoku66-2_HTML/2020N-04-01.pdf).

The process according to the embodiment of the present disclosure is applicable to the portions of the source electrodes that are surrounded by the broken-line circles and the portion of the drain electrode that is surrounded by the broken-line ellipse in FIG. 7. That is, in the device structure of the field effect transistor (FET) shown in FIG. 7, an n⁺⁺ layer or any other layer that reduces contact resistance is formed at the interface between the source electrode or the drain electrode and the semiconductor material. The process described in the embodiment is applied to the location described above, and a metal electrode serving as a source electrode or a drain electrode is formed on an SnO₂ layer as the dopant supply source, so that the SnO₂ layer is caused to function as a contact electrode.

### 7. EXAMPLE OF SN CONCENTRATION DISTRIBUTION

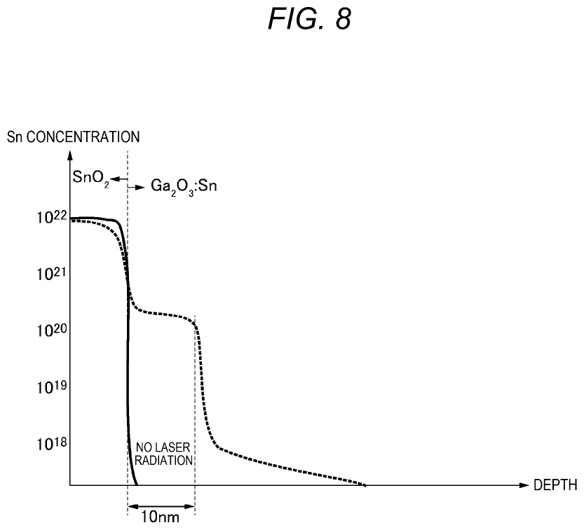

FIG. 8 is a graph showing an example of the distribution of the Sn concentration in the Ga₂O₃ to which Sn is doped by using the process described in the embodiment. The horizontal axis in FIG. 8 represents the depth in nanometers (nm). The vertical axis in FIG. 8 represents the Sn concentration in atoms/cm³. The solid-line graph in FIG. 8 represents the Sn concentration distribution before the laser light radiation (before doping), and the broken-line graph represents the Sn concentration distribution after the doping.

To reduce the contact resistance, it is desirable that the Sn concentration in the SnO₂ layer is higher than or equal to 10²¹ atoms/cm³, and that the Sn concentration in the Sn-doped Ga₂O₃ layer near the interface with the SnO₂ layer is higher than or equal to 10¹⁸ atoms/cm³. For example, in the Sn concentration distribution in the structure in which an SnO₂ layer is placed on a Ga₂O₃ layer, assuming that the interface between the two layers is present at the depth where the derivative of the concentration with respect to the depth is a maximum negative value, it is desirable that the Sn concentration is higher than or equal to 10¹⁸ atoms/cm³ in the portion from the interface to the depth of 10 nm. The Sn concentration in the portion from the interface to the depth of 10 nm is more desirably higher than or equal to 10¹⁹ atoms/cm³, and further desirably higher than or equal to 10²⁰ atoms/cm³. Note that the desirable conditions described above do not apply to doping performed to form an n-layer extending from the interface to a deeper region.

FIG. 8 shows a case where a doped region having an Sn concentration higher than or equal to 10²⁰ atoms/cm³ is formed in a region from the interface between the SnO₂ layer and the Ga₂O₃ layer to the depth of 10 nm. The region shown in FIG. 8 from the interface to the depth of 10 nm is an example of the “doped region having an Sn concentration higher than or equal to 10¹⁸ atoms/cm³” in the present disclosure. Adjusting the film thickness of each of the layers and the laser radiation conditions in accordance with the application and structure of the device to be produced allows formation of a doped region having a desired Sn concentration.

### 8. PROCESSOR

The processor, such as the laser controlling processor 28 and the laser radiation controlling processor 100, may be physically configured as hardware to execute the various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included in the present disclosure may be defined by a combination of control programs stored in the memories. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as a FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 9. OTHERS

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined. The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A semiconductor device manufacturing method comprising:
forming a tin-containing oxide film on a gallium-oxide-based compound;
irradiating the tin-containing oxide film with ultraviolet laser light to dope the gallium-oxide-based compound with tin; and
forming a metal electrode on the tin-containing oxide film irradiated with the ultraviolet laser light.

2. The semiconductor device manufacturing method according to claim 1, wherein
the tin-containing oxide film is made of tin dioxide.

3. The semiconductor device manufacturing method according to claim 1, wherein
the tin-containing oxide film is made of indium tin oxide or tin-doped indium oxide.

4. The semiconductor device manufacturing method according to claim 1, wherein
the gallium-oxide-based compound is gallium oxide.

5. The semiconductor device manufacturing method according to claim 4, wherein
the gallium-oxide-based compound is β-Ga₂O₃.

6. The semiconductor device manufacturing method according to claim 1, wherein
the ultraviolet laser light is KrF excimer laser light.

7. The semiconductor device manufacturing method according to claim 1, wherein
fluence of the ultraviolet laser light at the tin-containing oxide film is greater than or equal to 100 mJ/cm² but smaller than or equal to 400 mJ/cm².

8. The semiconductor device manufacturing method according to claim 1, wherein
a doped region having an Sn concentration higher than or equal to 10¹⁸ atoms/cm³ is formed by irradiating the tin-containing oxide film with the ultraviolet laser light to dope the gallium-oxide-based compound with tin.

9. The semiconductor device manufacturing method according to claim 1, wherein
an Sn concentration in the tin-containing oxide film is higher than or equal to 10²¹ atoms/cm³ when the tin-containing oxide film is irradiated with the ultraviolet laser light to dope the gallium-oxide-based compound with the tin, and
an Sn concentration in the tin-doped gallium-oxide-based compound is lower than 10²¹ atoms/cm³, and an Sn concentration in a portion from an interface between the tin-containing oxide film and the gallium-oxide-based compound to a depth of 10 nm is higher than or equal to 10¹⁸ atoms/cm³.

10. The semiconductor device manufacturing method according to claim 9, wherein
the Sn concentration in the portion from the interface to the depth of 10 nm is higher than or equal to 10¹⁹ atoms/cm³.

11. The semiconductor device manufacturing method according to claim 9, wherein
the Sn concentration in the portion from the interface to the depth of 10 nm is higher than or equal to 10²⁰ atoms/cm³.

12. The semiconductor device manufacturing method according to claim 1, wherein
the tin-containing oxide film is formed by sputtering or pulse laser deposition.

13. The semiconductor device manufacturing method according to claim 1, wherein
the tin-containing oxide film has a film thickness greater than or equal to 1 nm but smaller than or equal to 300 nm.

14. The semiconductor device manufacturing method according to claim 1, wherein
the metal electrode contains Au.

15. The semiconductor device manufacturing method according to claim 1, wherein
before the metal electrode is formed on the tin-containing oxide film,
a metal film containing any of Ti, Cr, and Ni is formed on the tin-containing oxide film.

16. A semiconductor device comprising: a gallium-oxide-based compound; and a tin-containing oxide film formed on the gallium-oxide-based compound,
an Sn concentration in the tin-containing oxide film being higher than or equal to 10²¹ atoms/cm³ when the tin-containing oxide film is irradiated with ultraviolet laser light to dope the gallium-oxide-based compound with tin, and
an Sn concentration in the tin-doped gallium-oxide-based compound being lower than 10²¹ atoms/cm³, and an Sn concentration in a portion from an interface between the tin-containing oxide film and the gallium-oxide-based compound to a depth of 10 nm being higher than or equal to 10¹⁸ atoms/cm³.

17. The semiconductor device according to claim 16, wherein
the Sn concentration in the portion from the interface to the depth of 10 nm is higher than or equal to 10¹⁹ atoms/cm³.

18. The semiconductor device according to claim 16, wherein
the Sn concentration in the portion from the interface to the depth of 10 nm is higher than or equal to 10²⁰ atoms/cm³.

19. The semiconductor device according to claim 16, wherein
a metal electrode is formed on the tin-containing oxide film irradiated with the ultraviolet laser light.
